(19) United States
(12) Patent Application Publication
(10) Pub. No.: US 2018/0267099 A1
(43) Pub. Date: Sep. 20, 2018

(54) A Reconfigurable Hardware Device for Providing a Reliable Output Signal as well as a Method for Providing Said Reliable Output

(71) Applicant: Topic IP2 B.V., Best (NL)

(72) Inventors: Dirk Van Den Heuvel, Best (NL); Rene Paul Peter Zenden, Best (NL)

(21) Appl. No.: 15/763,747

(22) PCT Filed: Sep. 29, 2016
(86) PCT No.: PCT/NL16/50667

§ 371 Date: Mar. 27, 2018

(30) Foreign Application Priority Data
Sep. 29, 2015 (NL) 2015524

(51) Int. Cl. G01R 31/317; H03K 19/177; G01R 31/3177

(52) U.S. Cl. CPC G01R 31/31703; G01R 31/3177; H03K 19/17728; H03K 19/17764

(57) ABSTRACT

A method to improve the reliability of a function using reconfigurable hardware device for providing a reliable output signal, said device comprising a pre-defined reconfigurable area having at least three separate function blocks each with an input and an output, which function blocks are each arranged to provide a same function to a signal provided to a corresponding input thereof, an output block connected to each of said outputs of said function blocks, wherein said output block is arranged to provide a single reliable output signal based on signals received from said function blocks, a detection manager arranged for detecting, in real-time or quasi real-time, an error in any of said functions of said function blocks, thereby identifying a faulty operating function block, by detecting that said signals from function blocks are not the same, a reconfiguration manager arranged for reconfiguring an identified faulty operating function block with said same function, wherein said reconfiguring being physically altering reconfigurable hardware device resources by programming said reconfigurable hardware device, and a verification manager arranged for verifying said function of said reconfigured function block.

### FIELD OF THE INVENTION

The invention generally relates to a reconfigurable hardware device, such as a Field Programmable Gate Array, FPGA, as well as a method using said reconfigurable hardware device.

### BACKGROUND

One of the existing problems in the art relates to the pre-mature operational failure of integrated circuits such as a Field Programmable Gate Array, FPGA. A known way to verify the operation of the integrated circuits is to incorporate Built-in self-test, BIST, logic to test the integrated circuits during production and/or operation thereof. In addition, redundancy may be added to the integrated circuits, thereby improving the overall reliability of the FPGA.

Different types of redundancy exist, such as hardware redundancy, information redundancy, time redundancy and software redundancy. Hardware redundancy is, for example, a triple modular redundancy which is a fault-tolerant form of N-modular redundancy, in which three systems perform a process and that result is processed by a majority-voting system to produce a reliable single output. If any one of the three systems fails, the other two systems can correct and mask the fault. Information redundancy is related to, for example, error detection and correction of data. Time redundancy is related to the act of performing the same operation multiple times such as multiple executions of a program or multiple copies of data transmitted. Finally, software redundancy is related to a method or process in software engineering wherein multiple functionally equivalent programs are independently generated from the same initial specifications.

Currently, a technique for addressing various yield problems includes using the BIST logic to detect some defective but replaceable logic during the production and fabrication process, and to bypass those elements that are found defective.

Yet another technique used to address yield problems due to pre-mature partial failures is a burn0in process that artificially ages the components being tested to eliminate those circuits in the components that experience early failures. If, after burn-in is completed, the BIST logic detects some defective but replaceable logic, permanent modification processes as described above may be used to bypass and/or replace the defective circuitry prior to distribution.

U.S. Pat. No. 7,529,998 discloses a reconfigurable circuit having primary function blocks with runtime built-in self-test, BIST, circuitry, for determining whether the primary function block is defective, a redundant function block having second BIST circuitry, the redundant function block configured to selectively implement the function in place of the primary function block if the primary function block is determined to be defective, and a rerouting coupler configured to implement reconfiguration information to reroute I/O signals from the primary function block to the redundant function block to facilitate replacement of the defective primary function block with the redundant function block based on a result of a test run of the first BIST circuitry of the primary function block.

A drawback of the above disclosed reconfigurable circuit is that reliability, and the lifespan, of the circuit is still limited. Further, often large sized reconfigurable circuits are required to accommodate the redundant function blocks which is basically a waste of resources.

It is therefore an object of the present invention, to provide for a reconfigurable hardware device for efficiently providing a reliable output signal, and for increasing the life expectancy of the device.

### SUMMARY

In order to accomplish that object, the invention, according to a first aspect thereof, provides for a reconfigurable hardware device for providing a reliable output signal, said device comprising:
a pre-defined reconfigurable area having at least one separate function block with an input and an output, which function block is arranged to provide a function to a signal provided to a corresponding input thereof,
a detection manager arranged for detecting, in real-time or quasi real-time, an error in said function of said at least one function block, thereby identifying a faulty operating function block;
a reconfiguration manager arranged for reconfiguring an identified faulty operating function block with said same function, wherein said reconfiguring being physically altering reconfigurable hardware device resources by programming said reconfigurable hardware device;
a verification manager arranged for verifying said function of said reconfigured function block.

In a more detailed example hereof, the invention provides for a reconfigurable hardware device for providing a reliable output signal, said device comprising a pre-defined reconfigurable area having at least three separate function blocks each with an input and an output, which function blocks are each arranged to provide a same function to a signal provided to a corresponding input thereof, an output block connected to each of said outputs of said at least three separate function blocks, wherein said output block is arranged to provide a single reliable output signal based on signals received from said at least three separate function blocks, a detection manager arranged for detecting, in real-time or quasi real-time, an error in any of said functions of said at least three separate function blocks, thereby identifying a faulty operating function block, by detecting that said signals from said at least three separate function blocks are not the same, a reconfiguration manager arranged for reconfiguring an identified faulty operating function block with said same function, wherein said reconfiguring being physically altering reconfigurable hardware device resources by programming said reconfigurable hardware device and a verification manager arranged for verifying said function of said reconfigured function block.

The invention is based on the perception that the reliability and the life expectancy of the reconfigurable hardware device is increased in case the device is capable to detect errors in any of the functions of the at least one separate function blocks itself, and to reconfigure a faulty operating function block with the same function itself, such that the functionality of the reconfigurable hardware device is restored again.

As such, the reconfigurable hardware device according to the present invention possesses the ability to restore itself, i.e. to detect and to correct faulty operating function blocks.

One of the advantages hereof is that maintenance personal does not need to approach and repair the reconfigurable hardware device each time a faulty operating function block has been detected, as the reconfigurable hardware device is capable to restore itself.

U.S. Pat. No. 7,529,998 discloses a finite amount of available redundancy blocks, and thus also a finite amount of repair possibilities. Each time a faulty redundancy block is detected, a rerouting takes place to remove that faulty redundancy block and to enable a further redundancy block, i.e. the faulty redundancy block is replaced by the further redundancy block. Another advantage the present invention has over U.S. Pat. No. 7,529,998 is that the amount of times a repair action can be performed is, in theory, unlimited, while in U.S. Pat. No. 7,529,998 the amount of times a repair action can be performed is directly related to the amount of available redundancy blocks.

Yet another advantage of the present invention, is that the reconfigurable areas of the reconfigurable hardware device, i.e. the areas comprising the separate function blocks, does not need to be large as the reconfigurable hardware device does not need to provide “back-up” function blocks. In case a faulty operating function block is detected, the corresponding reconfigurable area is reprogrammed to renew the function block.

As explained above, the reconfiguration manager is arranged to reconfigure an identified faulty operating function block with the same function, which means that the reconfiguration manager is arranged to physically alter the reconfigurable hardware device resources by programming the hardware device.

A reconfigurable hardware device, in the context of the present invention, comprises typically a plurality of configurable logic blocks, i.e. function blocks, and an interconnect structure for interconnecting the configurable logic blocks. A reconfigurable hardware device can be a logic gate array, e.g. an FPGA. Reconfiguring the hardware device means programming the functionality of the logic blocks, i.e. altering the actual hardware design of an FPGA, for example by using a partial bitstream as a result of the synthesis of a Very High Speed Integrated Circuit Hardware Description Language, VHDL, design. As such, reconfiguring is considered to be comprising the implementation of the functionality in the FPGA fabric.

In the context of the present invention, the reconfigurable hardware device according to the present invention may be a FPGA and/or may be implemented in a single casing, such as, for example, a Zynq-7000, Virtex-7, Kintex-7, and Artix-7 device platform.

In an embodiment, the output block is a N-modular redundancy output block providing said single output based on a majority voting based on said signals received from said at least three separate function blocks.

Advantageously, the reconfigurable hardware device comprises exactly three separate function blocks, wherein the output block is a two out of three modular output block.

In another embodiment, the detection manager is arranged for detecting an error in any of said functions of said at least three separate function blocks by:
providing a known test sequence to an function block of said at least three function blocks which provides an output deviating from a majority output of said at least three function blocks, and
detecting an error in said function of said function block provided with said known test sequence, by comparing said output of said function block provided with said known test sequence, with an expected output signal.

In case it is detected that the signals outputted by the at least three separate function blocks are not the same, it is concluded that there is at least one function block which is operating faulty. In order to detect which of the at least three separate function blocks is operating faulty, a known test sequence may be provided to the function block which provides an output deviating from a majority output of the at least three function blocks.

As the test sequence is known beforehand, and as the function of the function blocks is known beforehand, it is known what the output of the function block should be. An error in the function of the tested function block is detected in case the provided output of the function block deviates from the expected output of the function block. As such, the faulty function block is identified, or recognized, such that that function block is to be reconfigured.

In another embodiment, the detection manager is arranged for detecting an error in any of said functions of said at least three separate function blocks by:
providing a known test sequence to any function block of said at least three function blocks, and
detecting an error in said function of said function block provided with said known test sequence, by comparing said output of said function block provided with said known test sequence, with an expected output signal.

The inventors noted that, typically, it is likely that the function block providing an output deviating from the majority is the one that is operating faulty. However, it may occur that that function block is actually functioning correctly and that it is the remaining function blocks that function faulty. As such, the test sequence may also be provided to any of the function blocks to detect one or more faulty operating function blocks.

In a further embodiment, the verification manager is arranged for verifying said function of said reconfigured function block by:
providing a known test sequence to said reconfigured function block, and
verifying that said output signal of said reconfigured function block corresponds to an expected output signal.

In yet another embodiment, the device further comprises:
a monitoring and diagnostic manager arranged for issuing an alert message in case a faulty operating function block has been identified.

As mentioned above, it is not necessary for maintenance personal to repair the reconfigurable hardware device once a faulty operating function block has been detected. The reconfigurable hardware device is capable to restore itself. However, it may be advantage if the device comprises a monitoring and diagnostic manager for issuing an alert message in case a faulty operating function block has been identified, such that at least maintenance personal are able to check and/or the operating of the device.

In a second aspect of the invention, there is provided a method for providing a reliable output signal using a reconfigurable hardware device according to any of the previous claims, said method comprising the steps of:
receiving, by said at least three function blocks, a same input signal to each of their corresponding inputs, and providing, by said at least three function blocks, corresponding output signals to said output block;
providing, by said output block, said single reliable output signal based on said received output signals from said at least three function blocks;
detecting, by said detection manager, in real-time or quasi real-time, an error in any of said functions of said at least three separate function blocks, thereby identifying a faulty operating function block;
reconfiguring, by said reconfiguration manager, an identified faulty operating function block with said same function, wherein said reconfiguring being physically altering reconfigurable hardware device resources by programming said reconfigurable hardware device;
verifying, by said verification manager, said function of said reconfigured function block.

In accordance with the present invention, different aspects applicable to the above mentioned examples of the reconfigurable hardware device, including the advantages thereof, correspond to the aspects which are applicable to the method according to the present invention.

In an embodiment of the method, the step of detecting comprises:
detecting, by said detection manager, that said signals from said at least three separate function blocks are not the same.

The step of detecting may further comprise:
providing, by said detection manager, a known test sequence to an function block of said at least three function blocks which provides an output deviating from a majority output of said at least three function blocks, and
detecting, by said detection manager, an error in said function of said function block provided with said known test sequence, by comparing said output of said function block provided with said known test sequence, with an expected output signal.

The said step of detecting may further comprise:
providing, by said detection manager, a known test sequence to any function block of said at least three function blocks, and
detecting, by said detection manager, an error in said function of said function block provided with said known test sequence, by comparing said output of said function block provided with said known test sequence, with an expected output signal.

In an embodiment of the method, the step of verifying comprises:
providing, by said verification manager, a known test sequence to said reconfigured function block, and
verifying, by said verification manager, that said output signal of said reconfigured function block corresponds to an expected output signal.

In accordance with the present invention, the method may further comprise the step of:
issuing, by a monitoring and diagnostic manager comprised by said reconfigurable hardware device, an alert message in case a faulty operating function block has been identified.

In accordance with the present invention, a computing platform may be provided, comprising:
at least one reconfigurable hardware device such as a Field Programmable Gate Array, FPGA in accordance with any of the examples provided above;
at least one processor, such as a physical entity or implemented as a softcore, arranged for communicating with said reconfigurable hardware device;
an operating system arranged to be executed on said at least one processor and arranged for managing execution of at least one application comprising a plurality of processes, wherein said computing platform further comprises:
   a first programmed concurrent process execution frame work, comprised within said at least one reconfigurable hardware device, comprising of one or multiple pre-defined reconfigurable areas on said at least one reconfigurable hardware device and a routing infrastructure arranged to exchange data within said frame work, said computing platform further comprising a reconfigurable infrastructure arranged to re-program said reconfigurable areas;
   a library of re-locatable and instantaneously available user-defined hardware functions, wherein said hardware functions are compatible with said pre-defined reconfigurable areas in said concurrent execution frame work;
   a reconfiguring manager arranged for dynamically reconfiguring said reconfigurable hardware device at run-time based on processes to be executed and instantaneous available reconfigurable hardware device resources, wherein said reconfiguring being physically altering said reconfigurable hardware device resources by programming said hardware device;
   a task manager arranged for queue communicating with said reconfiguring manager and for scheduling said processes on either one of said at least one processor and said at least one reconfigurable hardware device.

The invention will now be explained in more detail with reference to the appended FIGURE, which merely serve by way of illustration of the invention and which must not be construed as being limitative thereto.

### BRIEF DESCRIPTION OF THE DRAWINGS

FIG. 1 shows, in a schematic form, a reliability block diagram illustrating a reconfigurable hardware device for providing a reliable output signal, in accordance with the present invention.

### DETAILED DESCRIPTION

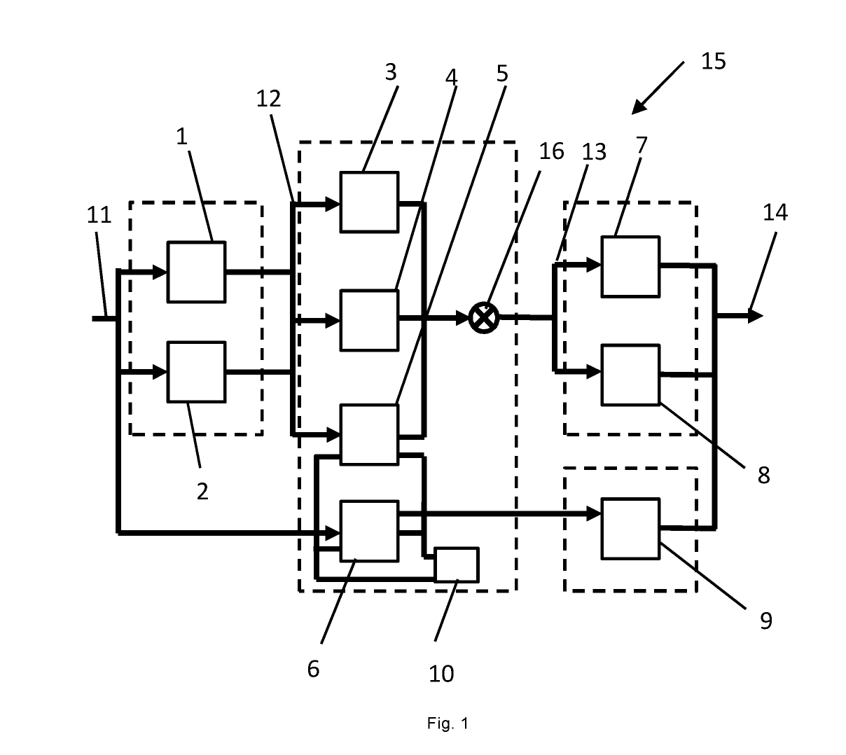

FIG. 1 shows, in a schematic form, a reliability block diagram 15 comprising a reconfigurable hardware device “B” according to the present invention.

Here, the reliability block diagram 15 consists of four components referred to with the letters “A”, “B”, “C” and “D”.

The component “A” is responsible for data acquisition and conditioning. For example, analogue to digital converters, A/D converters, 1, 2 convert an analogue input signal 11 to a digital output signal 12, which digital output signal 12 is to be provided to component “B”. The A/D converters 1, 2 may be deployed in a redundant manner, such that the reliability of the system increases.

The digital output signal 12 is provided to the input of the three function blocks 3, 4, 5. These function blocks thus perform the same function such that the output of each of these function blocks is the same, given that no function block is operating in a faulty manner.

The function blocks 3, 4, 5 are provided on a pre-defined reconfigurable area of the reconfigurable hardware device “B”. The function blocks 3, 4, 5 may be arranged to communicate directly with each other, for example for exchanging data or the like.

An output block 16 is connected to each of said outputs of the three separate function blocks 3, 4, 5, wherein said output block 16 is arranged to provide a single reliable output signal 13 based on signals received from said at least three separate function blocks.

Presently, the output block 16 is arranged as a two out of three redundant output block 16, such that the three function blocks 3, 4, 5 perform a process and that result is processed by a majority-voting system, i.e. two out of three, to produce a single output 13.

A detection manager, which is here incorporated in the output block 16, is arranged for detecting, in real-time or quasi real-time, an error in any of said functions of said three separate function blocks 4, 5, 6, thereby identifying a faulty operating function block, by detecting that said signals from said three separate function blocks are not the same.

The device “B” further comprises a reconfiguration manager 6 arranged for reconfiguring an identified faulty operating function block with said same function, wherein said reconfiguring being physically altering reconfigurable hardware device resources by programming said reconfigurable hardware device, and a verification manager 10 arranged for verifying said function of said reconfigured function block.

The output 13 of the output block 16 is then provided to component “C”, more specifically to a microcontroller in combination with a watchdog 7, 8. The microcontroller and the watchdog 7, 8 are arranged to control each other. When it is detected that on, or both, of the microcontrollers and the watchdog 7, 8 do not respond in time, the device will reset itself.

The present invention has been explained in the foregoing by means of a number of examples. As those skilled in the art will appreciate, several modifications and additions can be realised without departing from the scope of the invention as defined in the appended claims.

1. A reconfigurable hardware device for providing a reliable output signal, said device comprising:
a pre-defined reconfigurable area having at least one separate function block with an input and an output, which function block is arranged to provide a function to a signal provided to a corresponding input thereof, wherein said pre-defined reconfigurable area having at least three separate function blocks each with an input and an output which function blocks are each arranged to provide a same function to a signal provided to a corresponding input thereof,
an output block connected to each of said outputs of said at least three separate function blocks, wherein said output block is arranged to provide a single reliable output signal based on signals received from said at least three separate function blocks;
a detection manager arranged for detecting, in real-time or quasi real-time, an error in said function of said at least one function block, wherein said detection manager is arranged for detecting, in real-time or quasi real-time, an error in any of said functions of said at least three separate function blocks, thereby identifying a faulty operating function block, by detecting that said signals from said at least three separate function blocks are not the same;
a reconfiguration manager arranged for reconfiguring an identified faulty operating function block with said same function, wherein said reconfiguring being physically altering reconfigurable hardware device resources by programming said reconfigurable hardware device;
a verification manager arranged for verifying said function of said reconfigured function block, wherein said verification manager is arranged for verifying said function of said reconfigured function block by:
providing a known test sequence to said reconfigured function block, and
verifying that said output signal of said reconfigured function block corresponds to an expected output signal.

2. A reconfigurable hardware device according to claim 1, wherein said output block is an N-modular redundancy output block providing said single output based on a majority voting based on said signals received from said at least three separate function blocks.

3. A reconfigurable hardware device according to claim 1, wherein said detection manager is further arranged for detecting an error in any of said functions of said at least three separate function blocks by:
providing a known test sequence to any function block of said at least three function blocks, and
detecting an error in said function of said function block provided with said known test sequence, by comparing said output of said function block provided with said known test sequence, with an expected output signal.

4. A reconfigurable hardware device according to claim 1, wherein said device further comprises:
a monitoring and diagnostic manager arranged for issuing an alert message in case a faulty operating function block has been identified.

5. A method for providing a reliable output signal using a reconfigurable hardware device, said reconfigurable hardware device including:
a pre-defined reconfigurable area having at least one separate function block with an input and an output, which function block is arranged to provide a function to a signal provided to a corresponding input thereof, wherein said pre-defined reconfigurable area having at least three separate function blocks each with an input and an output which function blocks are each arranged to provide a same function to a signal provided to a corresponding input thereof,
an output block connected to each of said outputs of said at least three separate function blocks, wherein said output block is arranged to provide a single reliable output signal based on signals received from said at least three separate function blocks;
a detection manager arranged for detecting, in real-time or quasi real-time, an error in said function of said at least one function block, wherein said detection manager is arranged for detecting, in real-time or quasi real-time, an error in any of said functions of said at least three separate function blocks, thereby identifying a faulty operating function block, by detecting that said signals from said at least three separate function blocks are not the same;
a reconfiguration manager arranged for reconfiguring an identified faulty operating function block with said same function, wherein said reconfiguring being physically altering reconfigurable hardware device resources by programming said reconfigurable hardware device;
a verification manager arranged for verifying said function of said reconfigured function block, wherein said verification manager is arranged for verifying said function of said reconfigured function block, said method comprising the steps of:
receiving, by said at least three function blocks, a same input signal to each of their corresponding inputs, and providing, by said at least three function blocks, corresponding output signals to said output block;
providing, by said output block, said single reliable output signal based on said received output signals from said at least three function blocks;
detecting, by said detection manager, in real-time or quasi real-time, an error in any of said functions of said at least three separate function blocks, thereby identifying a faulty operating function block;
reconfiguring, by said reconfiguration manager, an identified faulty operating function block with said same function, wherein said reconfiguring being physically altering reconfigurable hardware device resources by programming said reconfigurable hardware device;
verifying, by said verification manager, said function of said reconfigured function block, wherein said step of verifying further comprises:
providing, by said verification manager, a known test sequence to said reconfigured function block, and
verifying, by said verification manager, that said output signal of said reconfigured function block corresponds to an expected output signal

6. A method for providing a reliable output signal according to claim 5, wherein said step of detecting further comprises:
providing, by said detection manager, a known test sequence to a function block of said at least three function blocks which provides an output deviating from a majority output of said at least three function blocks, and
detecting, by said detection manager, an error in said function of said function block provided with said known test sequence, by comparing said output of said function block provided with said known test sequence, with an expected output signal.

7. A method for providing a reliable output signal according to claim 6, wherein said step of detecting further comprises:
providing, by said detection manager, a known test sequence to any function block of said at least one function block, and
detecting, by said detection manager, an error in said function of said function block provided with said known test sequence, by comparing said output of said function block provided with said known test sequence, with an expected output signal.

8. A method for providing a reliable output signal according to claim 5, wherein said method further comprises the step of:
issuing, by a monitoring and diagnostic manager comprised by said reconfigurable hardware device, an alert message in case a faulty operating function block has been identified.
